(19) United States
(12) Patent Application Publication
(10) Pub. No.: US 2005/0061440 A1
(43) Pub. Date: Mar. 24, 2005

(54) Gas reaction chamber system having gas supply apparatus

(75) Inventor: Cheol Namgung, Suwon-si (KR)

Correspondence Address: Frank Chau, Esq.;F. CHAU & ASSOCIATES, LLC, 130 Woodbury Road, Woodbury, NY, 11797, US

(73) Assignee: SAMSUNG ELECTRONICS CO., LTD

(21) Appl. No.: 10/950,143

(22) Filed: Sep. 23, 2004

(30) Foreign Application Priority Data
Sep. 24, 2003 (KR) 2003-66326

(51) Int. Cl. C23F 1/00; H01L 21/306

(52) U.S. Cl. 156/345.29; 118/715

(57) ABSTRACT

Gas reaction chamber systems having a gas supply apparatus are provided. In one aspect, a reaction chamber system includes a reaction chamber, a plurality of gas supplies, and a plurality of gas supply conduits connecting the reaction chamber with the gas supplies. Gas supply valves are installed at each of the gas supply conduits, and a substitute gas supply conduit having a substitute gas supply valve is connected to at least one of the gas supply conduits. Thus, during interchanging of wafers, the substitute gas can be supplied into the reaction chamber system in substitution for the processing gases. As a result, the system can minimize an unnecessary consumption of processing gases.

### CROSS-REFERENCE TO RELATED APPLICATION

This application claims priority to Korean Patent Application No. 2003-66326, filed Sep. 24, 2003, which is incorporated herein by reference in its entirety.

### FIELD OF THE INVENTION

The present invention relates, generally, to an apparatus used in fabrication of semiconductor devices and, more particularly, to a gas reaction chamber system having a gas supply apparatus.

### BACKGROUND OF THE INVENTION

Typically, the fabrication of semiconductor devices includes a variety of process steps using processing gases, such as chemical vapor deposition (CVD) or dry etching processes. In these process steps, the processing gases are supplied into a reaction chamber through predetermined gas supply conduits. U.S. Pat. No. 6,508,913, entitled “Gas Distribution Apparatus For Semiconductor Processing”, discloses conventional embodiments in connection with gas supply conduits.

In the meantime, a multi-station processing chamber, as disclosed in U.S. Pat. Nos. 6,319,553, 5,882,417, and 5,679,405, has been used to increase the productivity of a deposition system in a CVD process.

FIG. 1 illustrates a conventional arrangement of a CVD system having a multi-station processing chamber.

Referring to FIG. 1, a plurality of processing gases 31, 32 and 33 are supplied through a plurality of gas supply conduits 61, 62, 63 and 64 into a reaction chamber 20 having several stations. Gas supply valves 41, 42, 43 and 44, filters 51, 52, 53 and 54, and mass flow controllers (MFCs) 55, 56, 57 and 58 are installed at the gas supply conduits 61, 62, 63 and 64, respectively. The gas supply conduits 61 and 62 may be joined together at a predetermined point, and the gas supply conduits 63 and 64 may be joined together at another predetermined point. Then, the gas supply conduits 61, 62, 63 and 64 joined together at the predetermined points are connected to the reaction chamber 20. Main supply valves 45 and 46 are installed at the joined conduits to control flows of processing gases 31, 32 and 33.

After performing a predetermined process, the processing gases supplied into the reaction chamber 20 are exhausted to the outside of the system 10 by means of an exhausting pump 26. The exhausting pump 26 is connected with the gas supply conduits 61, 62, 63 and 64 by means of exhausting conduits 65 and 66. Exhausting valves 47 and 48 are installed at the exhausting conduits 65 and 66, respectively, to control flowing paths of the processing gases 31, 32 and 33. The main supply valves 45 and 46 also take part in this control of gas flow.

The reaction chamber 20 is connected to a load-lock chamber 22. A deposition process comprises steps of loading wafers into the reaction chamber 20 and supplying the processing gases 31, 32 and 33 into the reaction chamber 20. In detail, in the loading step, the wafers contained in a wafer cassette are loaded from the outside of system 10 into the inside of load-lock chamber 22.

Meanwhile, during the deposition process, the reaction chamber 20 is maintained at the almost same pressure as the load-lock chamber 22. Thus, an additional step for controlling the pressure during a process of loading the wafers into the reaction chamber 20 is not required. As a result, such isobaric CVD system has by far a higher productivity than other type CVD systems where the pressure in the reaction chamber 20 is different from the load-lock chamber 22. However, A conventional isobaric CVD system, such as the one described above, may needlessly consume processing gases.

FIG. 2 is a timing diagram for explaining the consumption of processing gases occurring in the isobaric CVD system.

Referring FIGS. 1 and 2, a reaction of processing gases and a resultant deposition of a material layer occur at the second step when the processing gases are supplied with a radio-frequency (RF) power on.

In forth and fifth steps, the RF power is off during the process of loading a new wafer into the reaction chamber 20. The main supply valves 45 and 46 are closed and the exhausting valves 47 and 48 are opened so that the processing gases are not supplied into the reaction chamber 20 in forth and fifth steps. Thus, the processing gases are directly exhausted through the exhausting pump 26. Since such unnecessary consumption of processing gases reduces an exchanging period of gas bottles as the source of processing gases, a cost for fabricating the semiconductor devices may be increased and an efficiency of equipment may be decreased. Thus, it is necessary to provide a reaction chamber system capable of minimizing an unnecessary consumption of processing gases.

### SUMMARY OF THE INVENTION

In general, exemplary embodiments of the present invention include reaction chamber systems capable of minimizing an unnecessary consumption of processing gases. Furthermore, exemplary embodiments of the present invention include reaction chamber systems comprising gas supply apparatus for replacing a reaction gas with another gas.

More specifically, in one exemplary embodiment, a reaction chamber system comprises a reaction chamber, a plurality of gas supplies, and a plurality of gas supply conduits connecting the reaction chamber with the gas supplies. Gas supply valves are installed at each of the gas supply conduits, and a substitute gas supply conduit having a substitute gas supply valve is connected to at least one of the gas supply conduits. The substitute gas supply conduit is connected to the gas supply conduit between the reaction chamber and at least one of the gas supply valves.

According to another exemplary embodiment of the present invention, a gas-blocking valve is further installed at the gas supply conduit where the substitute gas supply conduit is connected. The gas-blocking valve is installed between the gas supply and the position where the substitute gas supply conduit and the gas supply conduit are joined together. Preferably, the gas supply valve and the substitute gas supply valve are a normal close type valve and the gas-blocking valve is a normal open type valve. The substitute gas supply valve and the gas-blocking valve may be a valve selected from a group consisting of solenoid valves, hydraulic valves, and pneumatic valves. And, the gas supply valve may be a valve selected from a group consisting of solenoid valves, hydraulic valves, and pneumatic valves.

According to another exemplary embodiment of the present invention, the system comprises a controller for controlling an opening state of the gas-blocking valve and the substitute gas supply valve. Preferably, the gas-blocking valve is closed by a signal of the controller and the substitute gas supply valve is opened by the same signal of the controller. Here, the gas-blocking valve and the substitute gas supply valve are preferably interlocked via a signal of a controller and simultaneously respond to the signal of the controller.

According to another exemplary embodiment of the present invention, a load-lock chamber is further disposed at one side of the reaction chamber. Here, the load-lock chamber is an isobaric type that is maintained at substantially the same pressure as the reaction chamber. Preferably, the pressure of the reaction chamber is lower than that of the load-lock chamber. More preferably, the pressure of the reaction chamber is about 1 to about 20% lower than the pressure of the load-lock chamber.

According to another exemplary embodiment of the present invention, filters and mass flow controllers may be disposed between the gas supply valves and the reaction chamber.

According to another exemplary embodiment of the present invention, the system comprises a pump for exhausting reaction gases supplied into the reaction chamber and an exhausting conduit connecting the pump with the reaction chamber. And, other exhausting conduits having exhausting valves may be installed between the pump and the gas supply conduits.

According to another exemplary embodiment, a radio-frequency power for activating the gases supplied into the reaction chamber may be connected to the reaction chamber. Preferably, the gas-blocking valve and the substitute gas supply valve are interlocked with the radio-frequency power via a controller.

According to another exemplary embodiment of the present invention, the substitute gas supply conduit may be connected to gas supplies for supplying nitrogen gas and argon gas.

These and other exemplary embodiments, features, aspects, and advantages of the present invention will be described and become apparent from the following detailed description of exemplary embodiments when read in conjunction with the accompanying drawings.

### BRIEF DESCRIPTION OF THE DRAWINGS

FIG. 1 illustrates a reaction chamber system having conventional gas supplying arrangements.

FIG. 2 is a timing diagram for explaining an operation of a reaction chamber system having conventional gas supplying arrangements as illustrated in FIG. 1.

FIGS. 3 to 6 illustrate reaction chamber systems according to exemplary embodiments of the present invention.

FIGS. 7 to 10 are timing diagrams for explaining methods of operating reaction chamber systems according to exemplary embodiments of the present invention.

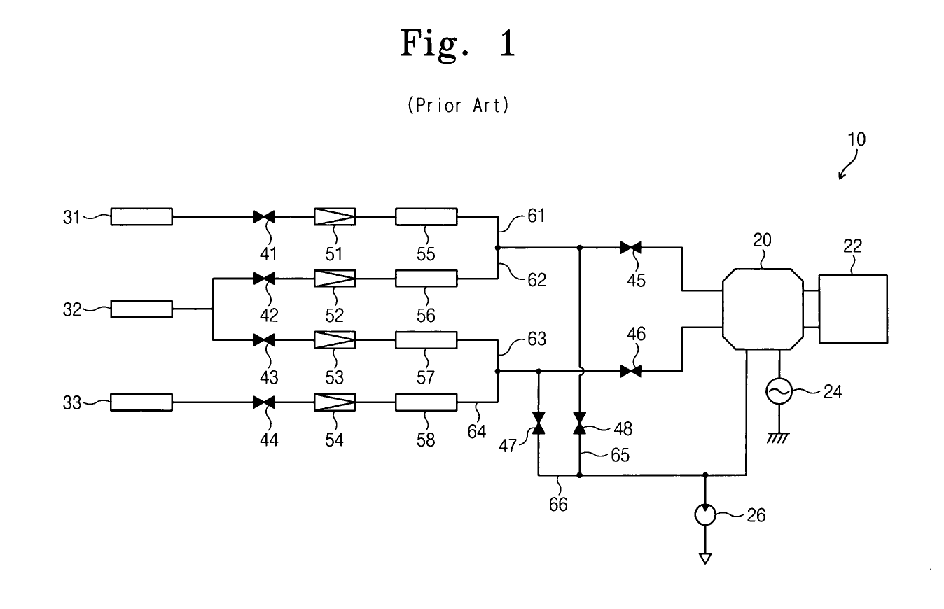

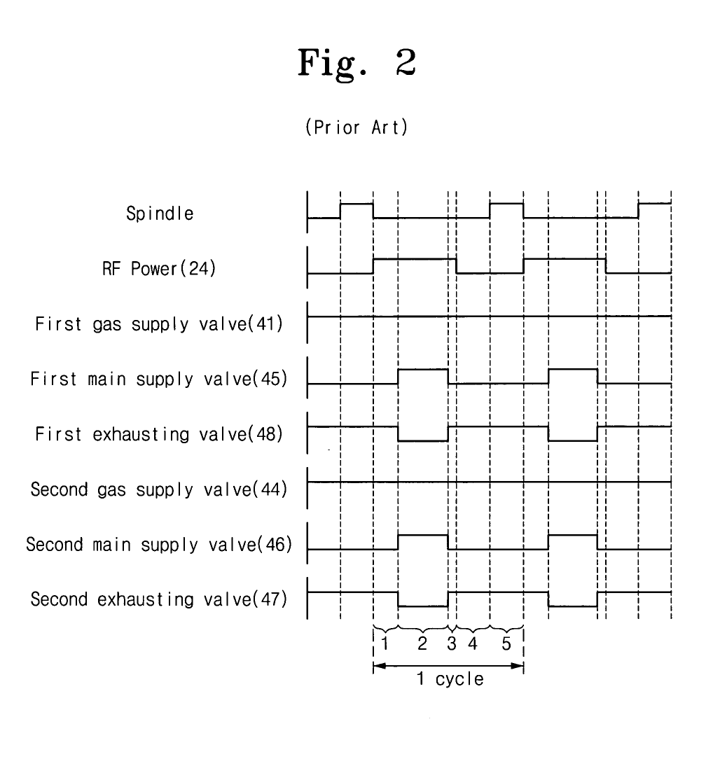

### DETAILED DESCRIPTION OF EXEMPLARY EMBODIMENTS

The present invention will now be described more fully hereinafter with reference to the accompanying drawings, in which exemplary embodiments of the invention are shown. This invention may, however, be embodied in different forms and should not be construed as limited to the exemplary embodiments set forth herein. Rather, these exemplary embodiments are provided so that this disclosure will be thorough and complete, and will fully convey the scope of the invention to those skilled in the art. Like numbers refer to like elements throughout the specification.

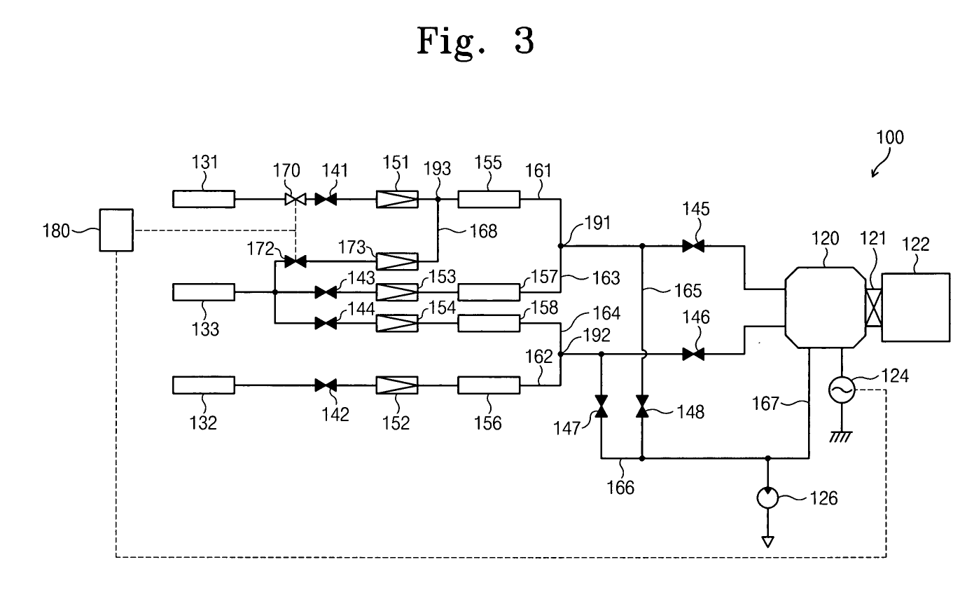

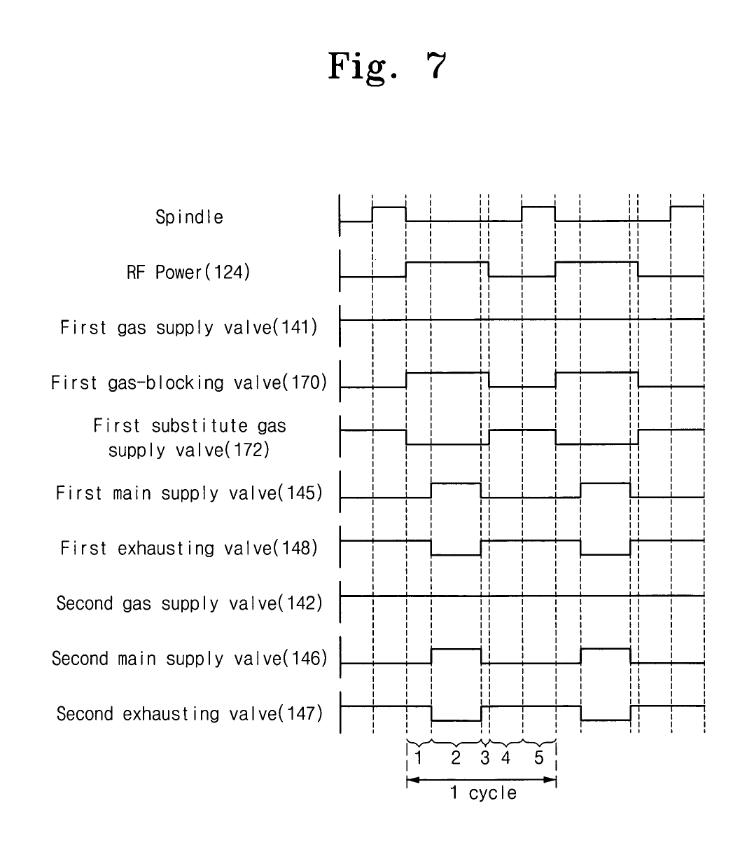

FIG. 3 illustrates a reaction chamber system according to one exemplary embodiment of the present invention, and FIG. 7 is a timing diagram for explaining a method of operating the reaction chamber system illustrated in FIG. 3, according to an exemplary embodiment of the present invention.

Referring to FIGS. 3 and 7, a reaction chamber system 100 according to one exemplary embodiment of the present invention comprises a reaction chamber 120 connected to a load-lock chamber 122. Preferably, to increase the production efficiency of system 100, the reaction chamber 120 comprises a multi-station processing chamber and a spindle that can be moved up and down.

It is desirable that the reaction chamber system 100 has an isobaric structure. In other words, it is necessary that a pressure difference between the reaction chamber 120 and the load-lock chamber 122 is maintained and that the pressure difference does not exceed a predetermined magnitude, e.g., about 20%. In particular, the pressure of the reaction chamber 120 is about 1 to about 20% lower than the pressure of the load-lock chamber 122 to prevent processing gases from leaking out of the reaction chamber 120.

According to another exemplary embodiment of the present invention, internal pressures of the reaction chamber 120 and the load-lock chamber 122 are about 2.2 Torr and about 2.5 Torr, respectively. The reaction chamber 120 is connected to a plurality of gas supplies including a first gas supply 131, a second gas supply 132, and a third gas supply 133. In order to make this connection to the reaction chamber 120, a plurality of gas supply conduits are placed between the reaction chamber 120 and the gas supplies 131, 132 and 133. For example, a first, second, and third gas supply conduits 161, 162 and 163 are attached to the first, second, and third gas supplies 131, 132 and 133, respectively.

According to this exemplary embodiment of the present invention, a fourth gas supply conduit 164 is further displaced between the reaction chamber 120 and the third gas supply 133. Here, the first gas supply conduit 161 and the third gas supply conduit 163 are joined together at a first position 191, and then connected to the reaction chamber 120. In addition, the second gas supply conduit 162 and the fourth gas supply conduit 164 are also joined together at a second position 192, and then connected to the reaction chamber 120. A first main supply valve 145 is installed between the first position 191 and the reaction chamber 120, and a second main supply valve 146 is installed between the second position 192 and the reaction chamber 120.

According to this exemplary embodiment of the present invention, the first, second and third gas supplies 131, 132 and 133 may be used for containing an oxygen-containing gas (e.g., nitrous oxide (N₂O)), a silicon-containing gas (e.g., silane (SiH₄)), and one of nitrogen gas (N₂) or inert gases including argon, neon or helium, respectively. Here, the fourth gas supply conduit 164 may be connected to an additional gas supply (not shown) instead of the third gas supply 133.

Gas supply valves 141, 142, 143 and 144, filters 151, 152, 153 and 154, and MFCs 155, 156, 157 and 158 are respectively installed at the gas supply conduits 161, 162, 163 and 164 in regular sequence. The gas supply valves 141, 142, 143 and 144 may be a normal close type. normal close type valves are closed until reception of a predetermined signal that causes the valve to open.

The reaction chamber 120 is connected to a radio frequency power 124 for activating the supplied processing gases and an exhausting pump 126 for exhausting the processing gases from the reaction chamber 120. The exhausting pump 126 is connected to the reaction chamber 120 through a chamber exhausting conduit 167. In addition, the exhausting pump 126 is connected to the first and second positions 191 and 192 through first and second exhausting conduits 165 and 166, respectively. A first exhausting valve 148 and a second exhausting valve 147 are installed at the first and second exhausting conduits 165 and 166, respectively. Preferably, the first and second exhausting valves 147 and 148 are of the normal close type.

A first substitute gas supply conduit 168 is installed between the first gas supply conduit 161 and the third gas supply 133. One endpoint of the first substitute gas supply conduit 168 is connected to a third position 193, which is a position between the first gas supply valve 141 and the first position 191, and other endpoint is connected to the third gas supply 133. A first substitute gas supply valve 172 is installed at the first substitute supply conduit 168, and a first gas-blocking valve 170 is installed at the first gas supply conduit 161. The first gas-blocking valve 170 is installed between the third position 193 and the first gas supply 131 and interlocked via a signal with the first substitute gas supply valve 172. Additionally, a controller 180 is connected to both the first gas-blocking valve 170 and the first substitute gas supply valve 172 to control operations of the valves. It is desirable that the controller 180 is electronically connected with the first gas-blocking valve 170 and the first substitute gas supply valve 172. And, the controller 180 may be used for monitoring and controlling operations of the radio frequency power 124.

The first gas-blocking valve 170 and the first substitute gas supply valve 172 are of the normal open type and a normal close type, respectively. In other words, the first gas-blocking valve is open and the first substitute gas supply valve 172 is closed until reception of a predetermined signal, which simultaneously causes the first gas-blocking valve to close and the first substitute gas supply valve 172 to open. The first gas-blocking valve 170 and/or the first substitute gas supply valve 172 are a valve selected from a group consisting of solenoid valves, hydraulic valves, and pneumatic valves. As aforementioned, the first gas-blocking valve 170 and the first substitute gas supply valve 172 are interlocked via a signal such that the first gas-blocking valve 170 and the first substitute gas supply valve 172 simultaneously respond to a signal of the controller 180.

Referring to FIG. 7, when the RF power 124 stops, the controller 180 transmits an operating signal to the interlocked valves 170 and 172 (S4). The operating signal simultaneously causes the first gas-blocking valve 170 to close and the first substitute gas supply valve 172 to open. Thus, during steps S4 and S5 of substituting wafers, a substitute gas, e.g., nitrogen gas contained in the third gas supply 133, can substitute for processing gases contained in the first gas supply 131, to prevent an unnecessary consumption of the processing gases. In addition, the substitute gas may be supplied from not only the third gas supply 133, but also an additional gas supply, not shown, containing other gases.

Next, when the RF power 124 starts again (S1), the operating signal of the controller 180 disappears so that the interlocked valves 170 and 172 are, respectively, restored to the ordinary states. In other words, the first gas-blocking valve 170 is opened while the first substitute gas supply valve 172 is closed. Thus, during operating of the RF power 124, the processing gas contained in the processing gas supply 131 (and not the substitute gas) is supplied into the reaction chamber 120 through the first main supply valve 145. In the meantime, the operating signal for restoring the interlocked valves 170 and 172 may be generated in a form of pulse.

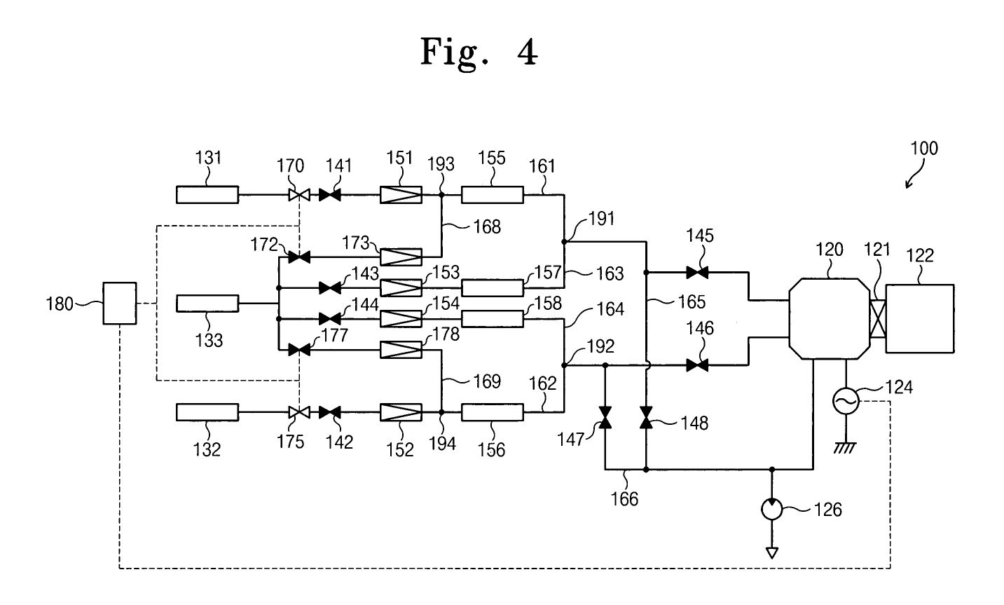

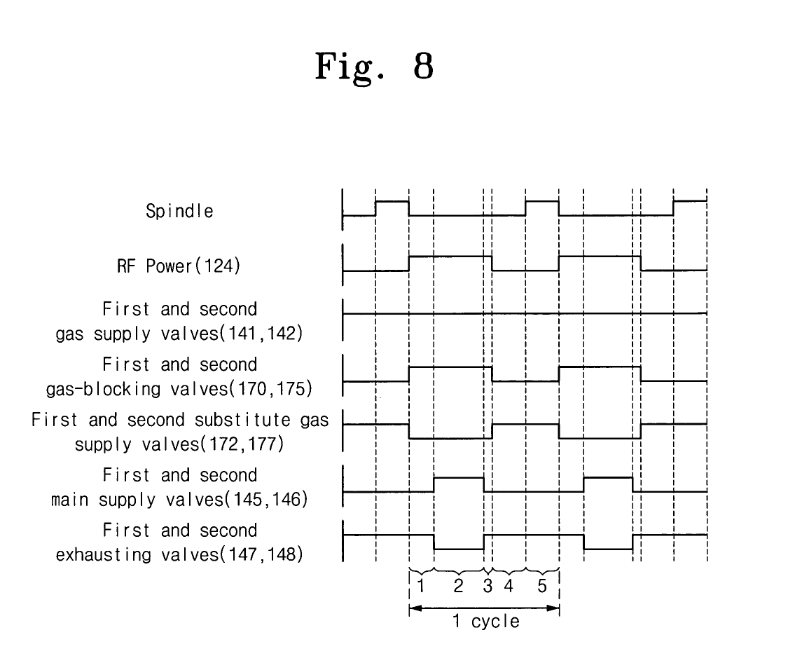

FIG. 4 illustrates a reaction chamber system according to another exemplary embodiment of the present invention, and FIG. 8 is a timing diagram for explaining a method of operating the reaction chamber system illustrated in FIG. 4, according to another exemplary embodiment. The exemplary reaction chamber illustrated in FIG. 4 has many similar parts as the exemplary embodiment explained by means of FIGS. 3 and 7, and parts where the exemplary embodiments differ are described below.

Referring to FIG. 4, one endpoint of a second substitute gas supply conduit 169 is connected to a fourth position 194, which is located at the second gas supply conduit 162. Particularly, the fourth position 194 is located between the second gas supply valve 142 and the second position 192. More particularly, the fourth position 194 is located between the second filter 152 and the second MFC 156. Other endpoint of the second substitute gas supply conduit 169 is connected to the third gas supply 133, but may be connected to another gas supply as stated above.

A second substitute gas supply valve 177 and filter 178 are installed at the second substitute gas supply conduit 169. In addition, a second gas-blocking valve 175 is installed at the second gas supply conduit 162, and the second gas-blocking valve 175 is interlocked via a signal with the second substitute gas supply valve 177. The second gas-blocking valve 175 is installed between the second gas supply 132 and the second gas supply valve 142. In structure and operation, a relation between the second gas-blocking valve 175 and the second substitute gas supply valve 177 is identical to that between the first gas-blocking valve 170 and the first substitute gas supply valve 172. Similarly, the second substitute gas supply valve 177 and the second gas-blocking valve 175 are interlocked via the signal. Simultaneously, the second substitute gas supply valve 177 and the second gas-blocking valve 175 respond to an operating signal transmitted from the controller 180.

Referring to FIG. 8, when the RF power 124 stops, the controller 180 transmits an operating signal to the interlocked valves 170, 172, 175 and 177 (S4). Simultaneously, the operating signal causes the first and second gas-blocking valves 170 and 175 to close and the first and second substitute gas supply valves 172 and 177 to open. Thus, during steps S4 and S5 of substituting wafers, a substitute gas, e.g., nitrogen gas contained in the third gas supply 133, can substitute for processing gases contained in the first and second gas supplies 131 and 132, to prevent an unnecessary consumption of them.

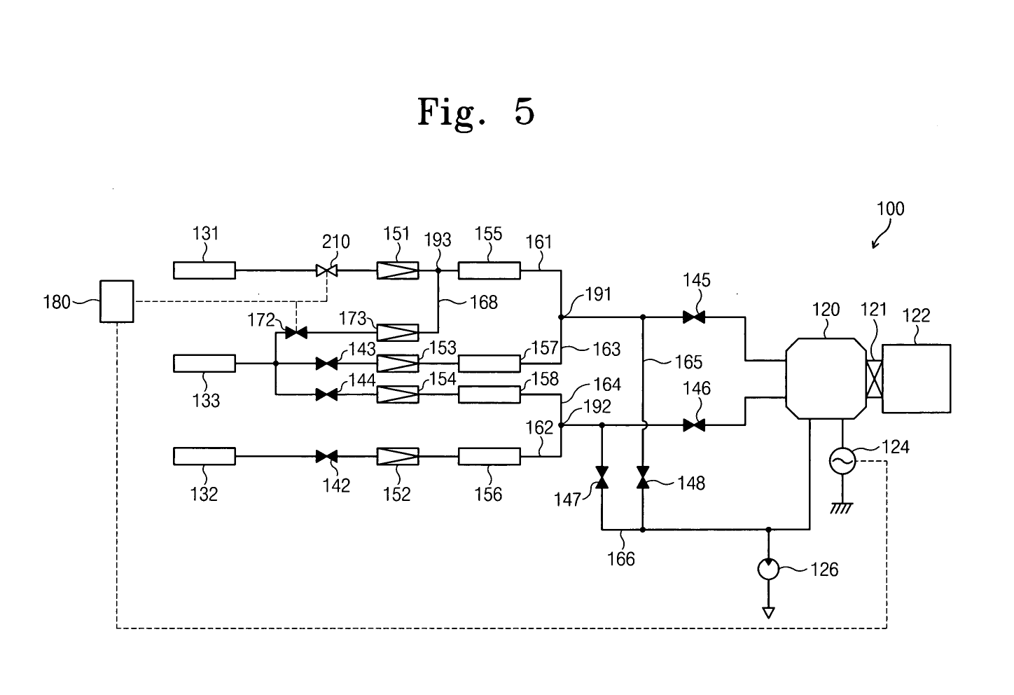

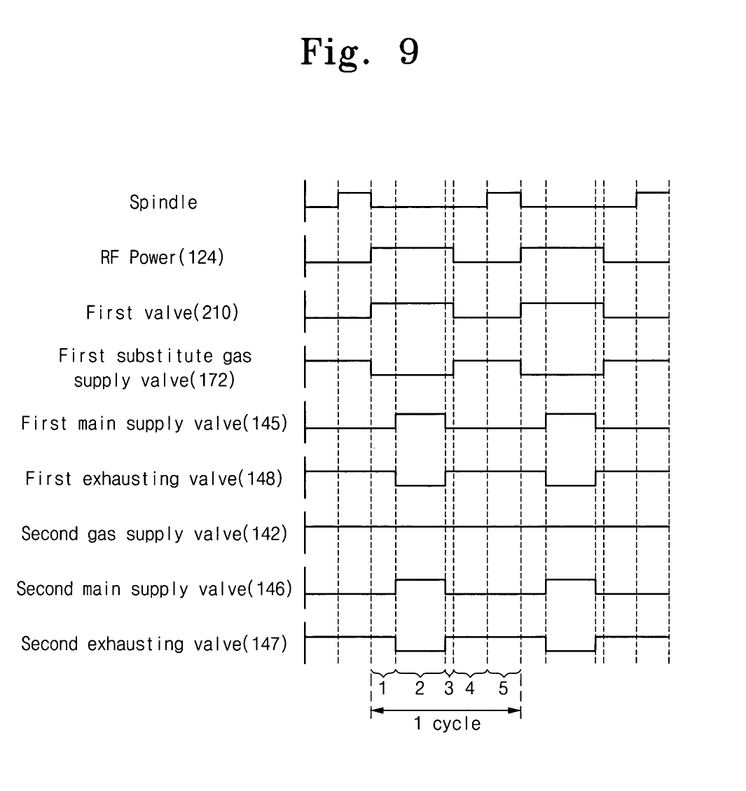

According to another exemplary embodiment of the present invention, a first valve 210 may be used instead of the first gas supply valve 141 and the first gas-blocking valve 170, as shown in FIG. 5. Similar to the exemplary embodiment as shown in FIG. 3, the first valve 210 is interlocked via a signal with the first substitute gas supply valve 172. The first valve 210 is closed for steps S4 and S5 of substituting wafers, and is opened for other period, i.e., steps S1, S2 and S3, as shown in FIG. 9. The first substitute gas supply valve 172 is opened, when the first valve 210 is closed.

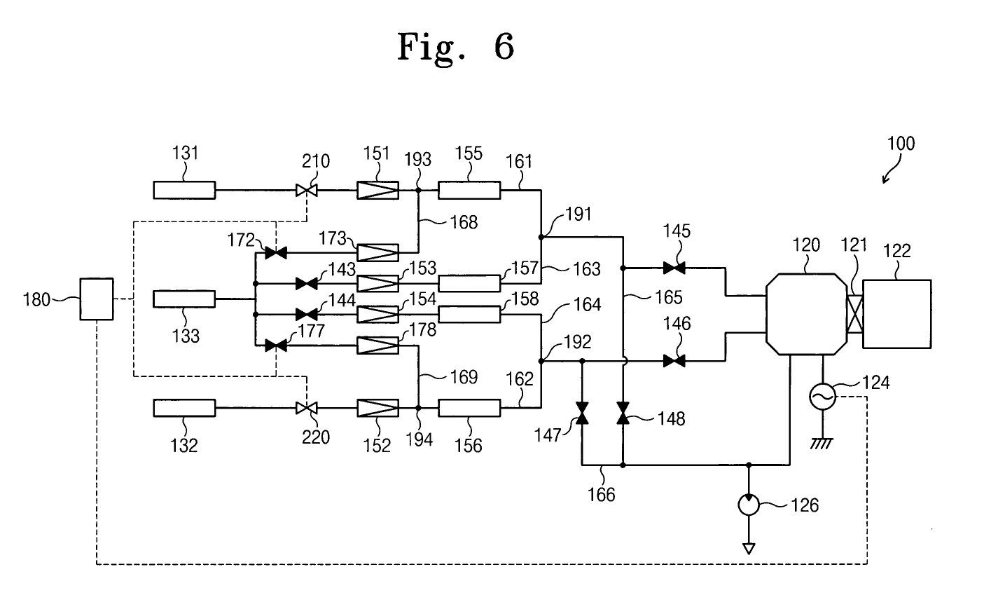

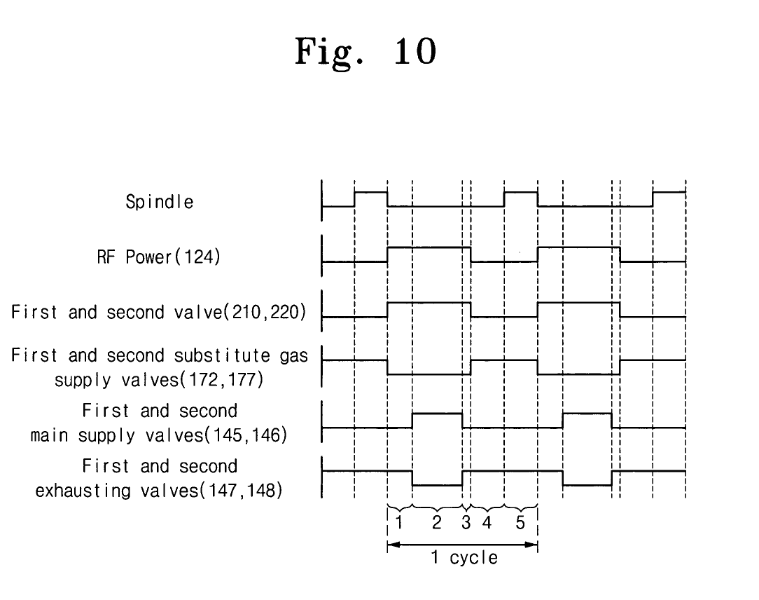

According to another exemplary embodiment of the present invention, in addition to the first valve 210, a second valve 220 may be installed to substitute for the second gas supply valve 142 and the second gas-blocking valve 175, as shown in FIG. 6. The second valve 220 is interlocked with the second substitute gas supply valve 177. The first and second valves 210 and 220 are closed for steps S4 and S5 of substituting wafers, to prevent an unnecessary consumption of the processing gases, as shown in FIG. 10. Further, the first and second substitute gas supply valves 172 and 177 are opened, when the first and second valves 210 and 220 are closed.

As stated above, during interchanging of wafers, the substitute gas, such as, nitrogen gas and so forth, is supplied into the reaction chamber system in substitution for the processing gases. Thus, the unnecessary consumption of processing gases can be minimized, and then extend an interchange period of the gas bottles. As a result, the system can be utilized effectively, and then it is possible to increase the productivity in the process for fabricating semiconductor devices.

1. A reaction chamber system comprising:
a reaction chamber;
a plurality of gas supplies;
a plurality of gas supply conduits connecting the reaction chamber with the gas supplies;
gas supply valves installed at each of the gas supply conduits;
a substitute gas supply conduit connected in parallel to one of the gas supply conduits, wherein the substitute gas supply conduit is joined at a position between the reaction chamber and one of the gas supply valves installed at the one of the gas supply conduits; and
a substitute gas supply valve installed at the substitute gas supply conduit.

2. The system of claim 1, further comprising a gas-blocking valve installed at a gas supply conduit where the substitute gas supply conduit is connected.

3. The system of claim 2, wherein the gas-blocking valve is installed between the gas supply and the position where the substitute gas supply conduit and the gas supply conduit are joined together.

4. The system of claim 2, wherein the gas supply valve and the substitute gas supply valve are a normal close type and the gas-blocking valve is a normal open type.

5. The system of claim 2, wherein the substitute gas supply valve and the gas-blocking valve are solenoid valves, hydraulic valves, or pneumatic valves.

6. The system of claim 1, wherein the gas supply valve is a solenoid valve, hydraulic valve, or pneumatic valve.

7. The system of claim 2, further comprising a controller for controlling an opening state of the gas-blocking valve and the substitute gas supply valve.

8. The system of claim 7, wherein the gas-blocking valve is closed by a signal of the controller,
the substitute gas supply valve is opened by the signal of the controller,
wherein the gas-blocking valve and the substitute gas supply valve are interlocked by the signal of the controller.

9. The system of claim 1, further comprising a load-lock chamber disposed at one side of the reaction chamber,
wherein the load-lock chamber is an isobaric type that is maintained at substantially the same pressure as the reaction chamber.

10. The system of claim 9, wherein the pressure of the reaction chamber is about 1 to about 20% lower than that of the load-lock chamber.

11. The system of claim 1, further comprising a filter disposed at each of the plurality of gas supply conduits between the gas supply valves and the reaction chamber.

12. The system of claim 1, further comprising a mass flow controller disposed at each of the plurality of gas supply conduits between the gas supply valves and the reaction chamber.

13. The system of claim 1, further comprising:
a pump for exhausting reaction gases supplied into the reaction chamber;
a first exhausting conduit connecting the pump with the reaction chamber;
second exhausting conduits connecting the pump with the gas supply conduits; and
an exhausting valve installed at each of the second exhausting conduits.

14. The system of claim 2, further comprising a radio-frequency power for activating the gases supplied into the reaction chamber,
wherein the gas-blocking valve and the substitute gas supply valve are interlocked with the radio-frequency power.

15. The system of claim 1, wherein the substitute gas supply conduit is connected to gas supplies for supplying nitrogen gas and argon gas.

16. A reaction chamber system comprising:
an isobaric type deposition chamber;
a first gas supply, a second gas supply and a third gas supply for supplying an oxygen-containing gas, a silicon-containing gas and a nitrogen-containing gas, respectively;
a first gas supply conduit, a second gas supply conduit and a third gas supply conduit for connecting the deposition chamber and the first, second and third gas supply conduits;
a first gas supply valve, a second gas supply valve and a third gas supply valve installed respectively at the first, second and third gas supply conduits, wherein the first, second and third gas supply valves being a normal close type;
a substitute gas supply conduit connected to the first gas supply conduit;
a substitute gas supply valve of a normal close type installed at the substitute gas supply conduit; and
a first gas-blocking valve of a normal open type installed at the first gas supply conduit,
wherein the gas-blocking valve and the substitute gas supply valve are interlocked together via a signal of a controller.

17. The system of claim 16, wherein the one end of the substitute gas supply conduit is connected to the first gas supply conduit between the deposition chamber and the first gas supply valve and the other end of the substitute gas supply conduit is connected to the third gas supply.

18. The system of claim 16, wherein the first gas-blocking valve is installed between the position where the substitute gas supply conduit and the first gas supply conduit are connected together and the first gas supply.

19. The system of claim 16, further comprising a controller for controlling an opening state of the first gas-blocking valve and the substitute gas supply valve,
wherein the first gas-blocking valve and the substitute gas supply valve are interlocked simultaneously by the signal of the controller.

20. The system of claim 16, further comprising a radio-frequency power for activating a reaction between the silicon-containing gas and the oxygen-containing gas supplied into the deposition chamber,
wherein the first gas-blocking valve and the substitute gas supply valve are interlocked with the radio-frequency power via the controller.
